(19) United States
(12) Patent Application Publication
(10) Pub. No.: US 2014/0217891 A1
(43) Pub. Date: Aug. 7, 2014

(54) ELECTRODE FOR PLASMA PROCESSING APPARATUS, METHOD FOR MANUFACTURING THE SAME, AND PLASMA PROCESSING APPARATUS

(71) Applicant: Kabushiki Kaisha Toshiba, Minato-ku (JP)

(72) Inventors: Hideo ETO, Yokkaichi-shi (JP); Hirokatsu Sonoda, Yokkaichi-shi (JP); Hisashi Hashiguchi, Yokkaichi-shi (JP); Makoto Saito, Nomi-shi (JP)

(73) Assignee: Kabushiki Kaisha Toshiba, Minato-ku (JP)

(21) Appl. No.: 14/167,364

(22) Filed: Jan. 29, 2014

(30) Foreign Application Priority Data
Feb. 1, 2013 (JP) 2013-018325

(51) Int. Cl. H01J 37/32; H01J 9/18

(52) U.S. Cl. CPC H01J 37/32568; H01J 37/32009; H01J 9/18
USPC 315/111.21; 313/326; 445/46

(57) ABSTRACT

According to embodiments, an inner electrode having a plurality of gas holes includes a first contact surface provided to a part of an outer peripheral surface. An outer electrode includes a second contact surface provided to a part of an inner peripheral surface, corresponding to the first contact surface of the inner electrode. The inner electrode and the outer electrode come into contact with each other on the first and second contact surfaces. A brazing filler metal is filled in a brazing filler metal filling hole that reaches from front side main surfaces of the inner electrode and the outer electrode to the contact surfaces to join the inner electrode and the outer electrode.

### CROSS-REFERENCE TO RELATED APPLICATIONS

This application is based upon and claims the benefit of priority from Japanese Patent Application No. 2013-18325, filed on Feb. 1, 2013; the entire contents of which are incorporated herein by reference.

### FIELD

The embodiments generally relate to an electrode for a plasma processing apparatus, a method for manufacturing the same, and a plasma processing apparatus.

### BACKGROUND

Conventionally, an electrode to a surface of which a plasma-resistant protective coating has been applied, and a plasma processing apparatus including the electrode are disclosed. Even the electrode having the plasma-resistant protective coating thereon deteriorates in long-term use. Especially, a gas hole provided to the electrode to supply fluorine gas and chlorine gas into a chamber is susceptible to deterioration.

### BRIEF DESCRIPTION OF THE DRAWINGS

FIGS. 1A to 1E are diagrams schematically illustrating manufacturing processes of an electrode for a plasma processing apparatus of a first embodiment;

FIGS. 2A to 2C are diagrams illustrating in detail parts of the manufacturing processes of the electrode for a plasma processing apparatus of the first embodiment;

FIGS. 3A and 3B are diagrams schematically illustrating an electrode for a plasma processing apparatus of a second embodiment;

FIGS. 4A and 4B are diagrams schematically illustrating manufacturing processes of an electrode for a plasma processing apparatus of a third embodiment;

FIG. 5 is a diagram schematically illustrating an intermediate stage of a manufacturing process of an electrode for a plasma processing apparatus of a fourth embodiment;

FIG. 6 is a diagram schematically illustrating an electrode for a plasma processing apparatus of a fifth embodiment; and

FIG. 7 is a cross-sectional view schematically illustrating a plasma processing apparatus of a sixth embodiment.

### DETAILED DESCRIPTION

The embodiments include an inner electrode where a plurality of gas holes constituting a gas flow passage for processing is formed, and an outer electrode to be joined on the outer periphery of the inner electrode. The inner electrode has a first contact surface provided to a part of an outer peripheral surface. The outer electrode has a second contact surface provided to a part of an inner peripheral surface, corresponding to the first contact surface of the inner electrode. The inner electrode and the outer electrode come into contact with each other on the first and second contact surfaces. An electrode for a plasma processing apparatus is provided, which includes a feature to be joined with a brazing filler metal filled in a brazing filler metal filling hole that reaches from main surfaces of the inner electrode and the outer electrode to the contact surfaces.

Hereinafter, a detailed description will be given of an electrode for a plasma processing apparatus, a method for manufacturing the same, and a plasma processing apparatus according to the embodiments with reference to the accompanying drawings. The present invention should not be limited by these embodiments.

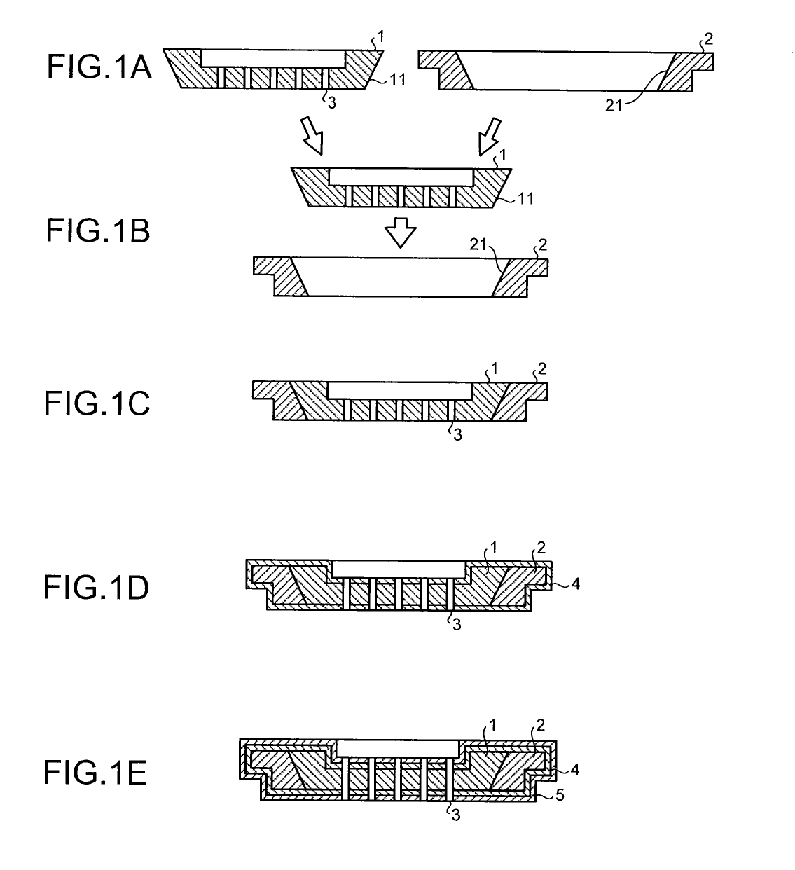

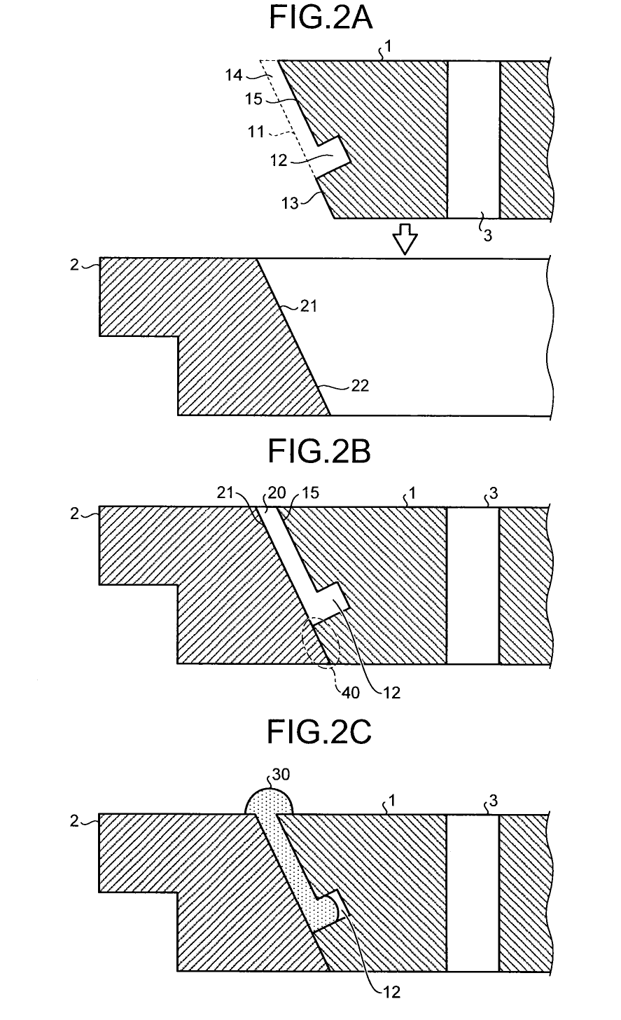

FIGS. 1A to 1E are diagrams schematically illustrating manufacturing processes of an electrode for a plasma processing apparatus of a first embodiment. Firstly, as illustrated in FIG. 1A, predetermined machining is performed to prepare an inner electrode 1 having a plurality of gas holes 3. The inner electrode 1 includes an inclined surface 11 that forms a predetermined tapered shape, and has a shape whose outer periphery is gradually reduced and become thinner toward a lower side. The inclined surface 11 is provided with a brazing filler metal filling hole (not illustrated) for filling a brazing filler metal. However, for convenience of description, the brazing filler metal filling hole is not described. Embodiments including the brazing filler metal filling hole will be described later. In addition, an outer electrode 2 is prepared, which includes a joint surface 21 having a reverse tapered slope corresponding to the inclined surface 11 of the inner electrode 1. The joint surface 21 of the outer electrode 2 has the slope corresponding to the slope of the inclined surface 11 of the inner electrode 1, and provides a reverse tapered shape where an inner periphery of an inner surface of the outer electrode 2 is gradually reduced toward a lower side. The inner electrode 1 and the outer electrode 2 are made of, for example, aluminum.

Next, the inner electrode 1 and the outer electrode 2 are positioned (FIG. 1B).

Next, the inner electrode 1 and the outer electrode 2 are fitted into each other (FIG. 1C). After the fitting, the brazing filler metal is filled in the brazing filler metal filling hole (not illustrated) formed between the joint surfaces of the inner electrode 1 and the outer electrode 2. A predetermined brazing filler metal rod (not illustrated) is pressed against the brazing filler metal filling hole and heated, and accordingly, the brazing filler metal melts to be filled in the brazing filler metal filling hole. The brazing filler metal is filled in the brazing filler metal filling hole in the principle of capillary action. The inner electrode 1 and the outer electrode 2 are joined by the filled brazing filler metal. An alloy having a lower melting point than aluminum being a material of the inner electrode and the outer electrode is selected as the brazing filler metal. It is possible to form a plurality of gas holes 3 after the inner electrode 1 and the outer electrode 2 are joined.

Next, an anodized aluminum coating 4 is formed on the inner electrode 1 and the outer electrode 2 by anodizing (FIG. 1D). This is for improving the corrosion resistance of the electrodes.

Next, an yttria coating 5 is formed on the anodized aluminum coating 4 by thermal spraying (FIG. 1E). The formation of the yttria coating 5 improves corrosion resistance to plasma.

The inner electrode 1 and the outer electrode 2 are joined with the brazing filler metal and accordingly the inner electrode and the outer electrode can be joined without melting. Therefore, the inner electrode 1 and the outer electrode 2 can be joined in a state where the shapes of both electrodes are maintained. The brazing filler metal is heated and melted to remove the inner electrode 1, and the processes described in FIGS. 1A to 1E are performed with a new inner electrode. Accordingly, the inner electrode can be renewed. Only the inner electrode 1 having the gas holes susceptible to deterioration can be renewed. Accordingly, it is more economical than a case where the entire electrode including the outer electrode 2 is renewed. Upon renewal of the inner electrode, it is also possible to adopt an inner electrode having an improved material different from the material of the inner electrode before renewal. Moreover, it is also possible to combine the inner electrode and the outer electrode 2 after forming predetermined protective coatings on the surface of the inner electrode.

Parts of the manufacturing processes of the electrode described in FIGS. 1A to 1E will be described in detail with reference to FIGS. 2A to 2C. Cross sections of a part of the electrode are schematically illustrated. FIG. 2A corresponds to the process of FIG. 1B. The inner electrode 1 provided with the plurality of gas holes 3 includes a first contact surface 13 on the inclined surface 11. In FIGS. 1A to 1E, the description was given as if the inner electrode 1 were joined on the inclined surface 11. However, actually the inner electrode 1 includes a joint surface 15 in a position recessed inward from the inclined surface 11 by the thickness of a processing portion 14 encircled by a dotted line. A brazing filler metal pool 12 is provided adjacent to the first contact surface 13. The outer electrode 2 includes, on the joint surface 21, a second contact surface 22 corresponding to the first contact surface 13 of the inner electrode 1. The second contact surface 22 of the outer electrode 2 has a slope corresponding to the tapered slope of the first contact surface 13 of the inner electrode 1, and forms the reverse tapered shape whose inner periphery of the inner surface of the outer electrode 2 is gradually reduced toward the lower side.

FIG. 2B illustrates a state where the inner electrode 1 and the outer electrode 2 are fitted into each other, and corresponds to the state of FIG. 10. The inner electrode 1 and the outer electrode 2 come into contact with each other at a portion indicated by a dot and dash line 40 on the first contact surface 13 and the second contact surface 22. An electrode structure is provided, where front side main surfaces (referring to main surfaces opposite to sides having the first contact surface 13 and the second contact surface 22. The same shall apply hereinafter) and back side main surfaces (referring to main surfaces on the sides having the first contact surface 13 and the second contact surface 22. The same shall apply hereinafter) of the inner electrode 1 and the outer electrode 2 respectively constitute one electrode surface. The inner electrode 1 and the outer electrode 2 are fitted into each other and accordingly a brazing filler metal filling hole 20 that reaches from the front side main surfaces of the inner electrode 1 and the outer electrode 2 to the first contact surface 13 and the second contact surface 22 is formed between the joint surface 15 constituting an outer peripheral surface of the inner electrode 1 and the joint surface 21 constituting an inner peripheral surface of the outer electrode 2. A melted predetermined brazing filler metal 30 is filled in the brazing filler metal filling hole 20 (FIG. 2C).

The inner electrode 1 and the outer electrode 2 come into contact with the first and second contact surfaces (13 and 22) having the predetermined tapers. The brazing filler metal 30 is filled up to the brazing filler metal pool 12 provided adjacent to the contact surface. Therefore, a structure is provided, where the brazing filler metal 30 is hard to be exposed to plasma, and it is possible to inhibit the diffusion of a contamination source existing in the brazing filler metal, for example, heavy metals such as iron and copper in a plasma processing apparatus. Moreover, the first and second contact surfaces (13 and 22) have the predetermined tapers. Accordingly, it is sufficient if the inner electrode 1 is inserted to be fitted until the first contact surface 13 of the inner electrode 1 comes into contact with the second contact surface 22 of the outer electrode, and the positioning of both electrodes is also easy.

In the above mentioned embodiment, the brazing filler metal pool 12 is provided on the surface of the inner electrode 1. It is also possible to provide the brazing filler metal pool 12 on the surface of the outer electrode 2 adjacent to the first and the second contact surfaces (13 and 22). Namely, the joint surface 15 and the brazing filler metal pool 12 can be provided by forming recessed portion positioned inward from the inner peripheral surface 21 of the outer electrode 2.

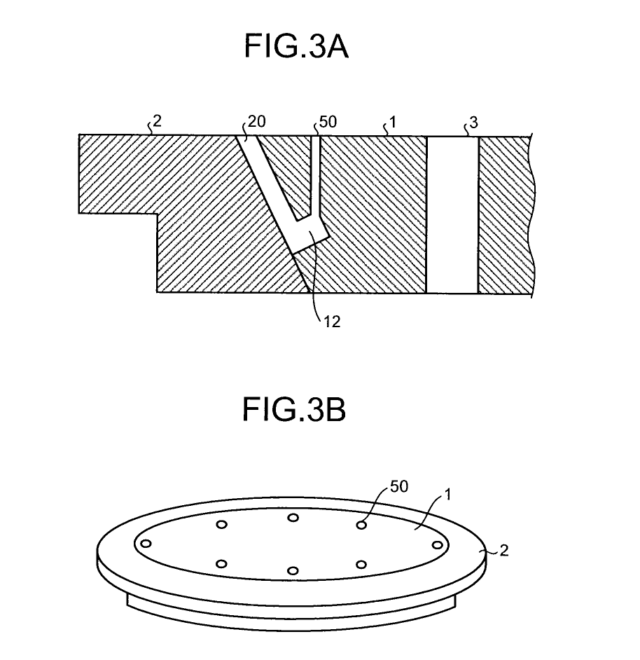

FIGS. 3A and 3B are diagrams schematically illustrating an electrode for a plasma processing apparatus of a second embodiment. FIG. 3A is a diagram schematically illustrating a cross section of a part of the electrode for a plasma processing apparatus of the second embodiment. In the embodiment, a bubble removal hole 50 reaching the brazing filler metal pool 12 is formed in an outer peripheral portion of the front side main surface of the inner electrode 1. It is possible to save the inconvenience that the brazing filler metal is not distributed into the brazing filler metal filling hole 20 due to a bubble (not illustrated) existing in the brazing filler metal filling hole when the brazing filler metal is filled in the brazing filler metal filling hole 20. The bubble removal hole 50 can be formed by drilling concurrently with the formation of the gas holes 3. FIG. 3B is a perspective view schematically illustrating a state where the bubble removal holes 50 are formed. The bubble removal holes 50 are formed at predetermined intervals in the outer peripheral portion on the front side main surface of the inner electrode 1. The gas holes formed in the inner electrode 1 are not illustrated. The bubble removal holes 50 are blocked by a predetermined process after the filling of the brazing filler metal. For example, they can be blocked by a process where the vicinities of the bubble removal holes 50 are pressurized and plastic-deformed. Predetermined protective coatings, for example, an anodized aluminum coating and an yttria coating are formed on the surface of the electrodes after joining with the brazing filler metal, which is not illustrated.

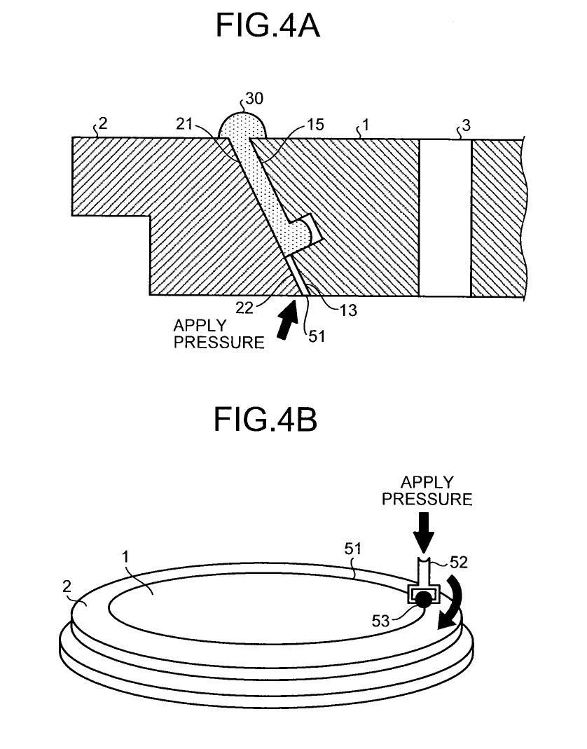

FIGS. 4A and 4B are diagrams schematically illustrating manufacturing processes of an electrode for a plasma processing apparatus of a third embodiment. The same reference numerals are assigned to components corresponding to the components described in FIGS. 2A to 2C and FIGS. 3A and 3B, and their descriptions will not be repeated. FIG. 4A schematically illustrates cross sections of parts of the inner electrode 1 and the outer electrode 2, and illustrates a state where they are ill fitted, and a gap 51 is created between the first contact surface 13 of the inner electrode 1 and the second contact surface 22 of the outer electrode 2. A predetermined heat/pressure processing is performed to block the gap 51.

FIG. 4B illustrates an example of the embodiment of the pressure processing. For convenience's sake, the electrode surface side opposed to a plasma processing chamber side of the plasma processing apparatus (not illustrated) is faced upward and illustrated. The gas holes are formed in the inner electrode 1, but are not illustrated. Pressure is applied by a pressure roller 52 along an inner periphery of the back side main surface of the outer electrode 2, the back side main surface being the side having the second contact surface 22. The pressure roller 52 includes, for example, a spherical pressure ball 53, and applies pressure on the surface in the vicinity of the inner periphery on the back side main surface of the outer electrode 2 by the pressure applied to contacts of the pressure ball 53 and the outer electrode 2. It is possible to plastic-deform a part of the vicinity of the inner periphery of the back side main surface of the outer electrode 2 by the application of pressure and to block the gap 51. Consequently, the brazing filler metal 30 will not be exposed to plasma, and a situation where the chamber of the plasma processing apparatus is contaminated can be prevented. At this point, the pressure ball 53 is heated and accordingly the gap 51 can be blocked more efficiently.

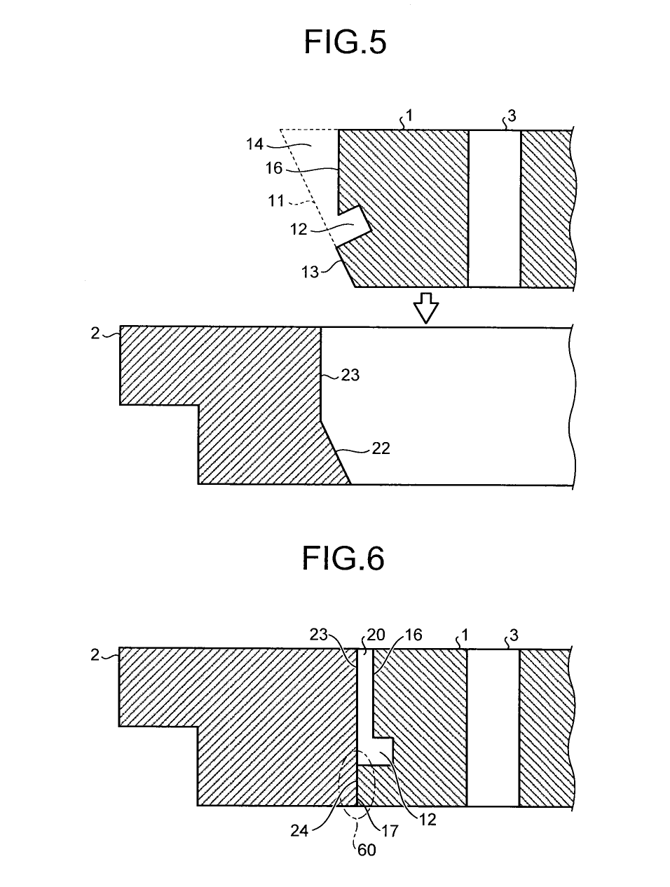

FIG. 5 is a diagram schematically illustrating an intermediate stage of a manufacturing process of an electrode for a plasma processing apparatus of a fourth embodiment. Cross sections of a part of the electrode are schematically illustrated. The same reference numerals are assigned to components corresponding to the components of the first to third embodiments, and their descriptions will not be repeated. In the embodiment, the inner electrode 1 includes the first contact surface 13 existing on the inclined surface 11 having the predetermined taper. The brazing filler metal pool 12 is provided adjacent to the first contact surface 13. A joint surface 16 is included, which extends to the brazing filler metal pool 12 vertically to the front side main surface of the inner electrode 1. It is an electrode structure including the joint surface 16 extending vertically to the front side main surface. The joint surface 16 of the inner electrode 1 is formed in a position recessed inward from the inclined surface 11 of the inner electrode 1 by the thickness of the processing portion 14 indicated by a dotted line. The outer electrode 2 includes a joint surface 23 extending vertically to the front side main surface, corresponding to the joint surface 16 of the inner electrode 1. The brazing filler metal filling hole (not illustrated) is formed between the joint surface 16 of the inner electrode 1 and the joint surface 23 of the outer electrode 2 to be filled with the brazing filler metal in the following process of fitting the inner electrode 1 and the outer electrode 2 into each other. Predetermined protective coatings, for example, an anodized aluminum coating and an yttria coating are formed on the surface of the electrodes after joining by filling of the brazing filler metal, which is not illustrated.

Also in the embodiment, both electrodes come into contact on the first contact surface 13 of the inner electrode 1 having the predetermined taper and the second contact surface 22 of the outer electrode 2 having the inclined surface of the reverse taper corresponding to the taper of the first contact surface 13. Accordingly, a structure is provided, where the brazing filler metal filled in the brazing filler metal filling hole is hard to be exposed to plasma. It is also possible to perform the pressurizing process by the pressure roller described in FIG. 4B in the vicinity of the inner periphery of the back side main surface on the second contact surface 22 side of the outer electrode 2 in order to ensure the contact of both electrodes on the first and second contact surfaces (13 and 22).

In the above mentioned embodiment, the brazing filler metal pool 12 is provided on the surface of the inner electrode 1. It is also possible to provide the brazing filler metal pool 12 on the surface of the outer electrode 2 adjacent to the first and the second contact surfaces (13 and 22). Namely, the joint surface 16 and the brazing filler metal pool 12 can be provided by forming recessed portion positioned inward from the inner peripheral surface 23 of the outer electrode 2.

FIG. 6 is a diagram schematically illustrating an electrode for a plasma processing apparatus of a fifth embodiment. Cross sections of a part of the electrode are schematically illustrated. The same reference numerals are assigned to components corresponding to the components of the first to fourth embodiments, and their descriptions will not be repeated. In the embodiment, a first contact surface 17 of the inner electrode 1 includes a vertical surface to the front side main surface of the inner electrode. A second contact surface 24 of the outer electrode 2 also includes a vertical surface to the front side main surface of the outer electrode 2, corresponding to the first contact surface 17 of the inner electrode. The inner electrode 1 and the outer electrode 2 are fitted into each other, and come into contact at a portion indicated by a dot and dash line 60 on the first contact surface 17 and the second contact surface 24. The brazing filler metal (not illustrated) is filled in the brazing filler metal filling hole 20 formed between the joint surface 16 of the inner electrode 1 and the joint surface 23 of the outer electrode 2. Predetermined protective coatings, for example, an anodized aluminum coating and an yttria coating are formed on the surfaces of the inner electrode 1 and the outer electrode 2 after joining with the brazing filler metal, which is not illustrated. The embodiment also has a configuration where the brazing filler metal is filled up to the brazing filler metal pool 12 and both electrodes come into contact on the first and second contact surfaces (17 and 24) formed on both electrodes, and accordingly, has a structure where the brazing filler metal is hard to be exposed to plasma.

In the above mentioned embodiment, the brazing filler metal pool 12 is provided on the surface of the inner electrode 1. It is also possible to provide the brazing filler metal pool 12 on the surface of the outer electrode 2 adjacent to the first and the second contact surfaces (17 and 24). Namely, the joint surface 16 and the brazing filler metal pool 12 can be provided by forming recessed portion positioned inward from the inner peripheral surface 23 of the outer electrode 2.

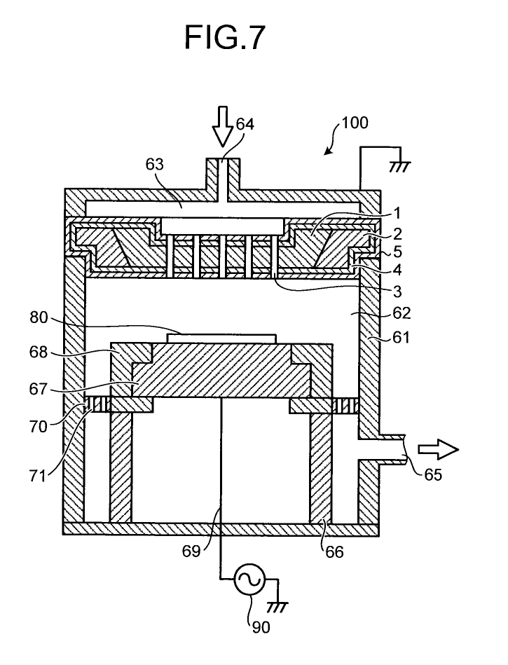

FIG. 7 is a cross-sectional view schematically illustrating a plasma processing apparatus of a sixth embodiment. A RIE (Reactive Ion Etching) apparatus is illustrated as the plasma processing apparatus. A plasma processing apparatus 100 includes a chamber 61 constructed to be air-tight. The chamber 61 is electrically grounded. A support table 67 is included in the chamber 61. A semiconductor wafer 80 being a target to be processed is placed on the support table 67. The support table 67 is supported by a support portion 66 via an insulating ring 68. A baffle plate 70 including a plurality of gas exhaust holes 71 is placed between the insulating ring 68 and the chamber 61. A radio-frequency power source 90 is connected to the support table 67 via a supply line 69. The support table 67, which has an electrostatic chuck (not illustrated), acts as a lower electrode.

The above-mentioned electrode structure including the inner electrode 1 and the outer electrode 2 is placed as an upper electrode above the support table 67, the electrode structure facing against the support table 67 acting as the lower electrode. The back side main surfaces where the contact surfaces are formed are placed so as to face a plasma processing chamber 62 side. Predetermined fluorine or chloride gas is supplied from a gas supply port 64 to a gas supply chamber 63. The supplied gas is supplied from the gas hole 3 of the upper electrode to the plasma processing chamber 62. The chamber 61 includes a gas exhaust port 65.

The structure where the brazing filler metal is hard to be exposed to plasma is adopted as the upper electrode of the plasma processing apparatus of the embodiment. Accordingly, it is possible to avoid contamination in the chamber due to the content of the brazing filler metal, for example, heavy metals such as iron and copper.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electrode for a plasma processing apparatus, comprising:
an inner electrode where a plurality of gas holes constituting a gas flow passage for processing is formed; and
an outer electrode to be joined to the inner electrode on an outer periphery of the inner electrode, wherein
the inner electrode includes a first contact surface provided to a part of an outer peripheral surface of the inner electrode,
the outer electrode includes a second contact surface provided to a part of an inner peripheral surface of the outer electrode, corresponding to the first contact surface of the inner electrode, and
the inner electrode and the outer electrode are possible to come into contact with each other on the first and second contact surfaces, and to be joined with a joint material to be filled in a hole between the inner electrode and the outer electrode, wherein the hole reaches from front side main surfaces of the inner electrode and the outer electrode to the first and second contact surfaces.

2. The electrode for a plasma processing apparatus according to claim 1, wherein the joint material includes a brazing filler metal.

3. The electrode for a plasma processing apparatus according to claim 2, wherein
the first contact surface of the inner electrode constitutes a taper-shaped inclined surface, and
the second contact surface of the outer electrode constitutes a reverse taper-shaped inclined surface including a slope corresponding to the slope of the first contact surface of the inner electrode.

4. The electrode for a plasma processing apparatus according to claim 3, wherein a part of the outer peripheral surface of the inner electrode adjacent to the first contact surface of the inner electrode includes a brazing filler metal pool formed inward of the inner electrode.

5. The electrode for a plasma processing apparatus according to claim 4, wherein a hole reaching from the front side main surface of the inner electrode to the brazing filler metal pool is provided to an outer peripheral portion of the inner electrode.

6. The electrode for a plasma processing apparatus according to claim 1, wherein a part of the inner peripheral surface of the outer electrode adjacent to the second contact surface of the outer electrode includes a brazing filler metal pool formed inward of the outer electrode.

7. A plasma processing apparatus comprising:
a plasma processing chamber; and
an electrode including:
an inner electrode having:
an outer peripheral surface;
a plurality of gas holes constituting a gas flow passage for processing; and
a first contact surface provided to a part of the outer peripheral surface; and
an outer electrode having:
an inner peripheral surface; and
a second contact surface provided to a part of the inner peripheral surface corresponding to the first contact surface of the inner electrode and configured to come into contact with the first contact surface of the inner electrode.

8. The plasma processing apparatus according to claim 7, wherein
the first contact surface of the inner electrode constitutes a taper-shaped inclined surface, and
the second contact surface of the outer electrode constitutes a reverse taper-shaped inclined surface including a slope corresponding to the slope of the first contact surface of the inner electrode.

9. The plasma processing apparatus according to claim 8, wherein a part of the outer peripheral surface of the inner electrode adjacent to the first contact surface of the inner electrode includes a brazing filler metal pool formed inward of the inner electrode.

10. The plasma processing apparatus according to claim 9, wherein a hole reaching from a front side main surface of the inner electrode to the brazing filler metal pool is provided to an outer peripheral portion of the inner electrode.

11. The plasma processing apparatus according to claim 10, wherein a back side main surface of the inner electrode and a back side main surface of the outer electrode are placed facing the plasma processing chamber of the plasma processing apparatus.

12. The plasma processing apparatus according to claim 7, wherein a part of the outer peripheral surface of the inner electrode adjacent to the first contact surface of the inner electrode includes a brazing filler metal pool formed inward of the inner electrode.

13. The plasma processing apparatus according to claim 7, wherein a back side main surface of the inner electrode and a back side main surface of the outer electrode are placed facing the plasma processing chamber side of the plasma processing apparatus.

14. The plasma processing apparatus according to claim 13, wherein a part of the outer peripheral surface of the inner electrode adjacent to the first contact surface of the inner electrode includes a brazing filler metal pool formed inward of the inner electrode.

15. A method for manufacturing an electrode for a plasma processing apparatus, comprising the steps of:
preparing an inner electrode, the inner electrode including a first contact surface on a part of an outer peripheral surface;
preparing an outer electrode including a second contact surface corresponding to the first contact surface of the inner electrode, on a part of an inner peripheral surface;
bringing at least parts of the first contact surface of the inner electrode and the second contact surface of the outer electrode into contact; and
filling a brazing filler metal in a brazing filler metal filling hole formed between the outer peripheral surface of the inner electrode and the inner peripheral surface of the outer electrode in the step of bringing the inner electrode and the outer electrode into contact.

16. The method for manufacturing an electrode for a plasma processing apparatus according to claim 15, comprising the step of applying pressure along an inner periphery of a back side main surface on the second contact surface side of the outer electrode.

17. The method for manufacturing an electrode for a plasma processing apparatus according to claim 16, wherein
the first contact surface of the inner electrode constitutes a taper-shaped inclined surface, and
the second contact surface of the outer electrode constitutes a reverse taper-shaped inclined surface including a slope corresponding to the slope of the first contact surface of the inner electrode.

18. The method for manufacturing an electrode for a plasma processing apparatus according to claim 17, wherein a part of the outer peripheral surface of the inner electrode adjacent to the first contact surface of the inner electrode includes a brazing filler metal pool formed inward of the inner electrode.

19. The method for manufacturing an electrode for a plasma processing apparatus according to claim 15, wherein
the first contact surface of the inner electrode constitutes a taper-shaped inclined surface, and
the second contact surface of the outer electrode constitutes a reverse taper-shaped inclined surface including a slope corresponding to the slope of the first contact surface of the inner electrode.

20. The method for manufacturing an electrode for a plasma processing apparatus according to claim 19, comprising the step of applying pressure along an inner periphery of a back side main surface on the second contact surface side of the outer electrode.
